(19) United States
(12) Patent Application Publication
(10) Pub. No.: US 2007/0290191 A1
(43) Pub. Date: Dec. 20, 2007

(54) Resonant cavity optoelectronic device with suppressed parasitic modes

(76) Inventors: Vitaly Shuchukin, (US); Nikolai Ledentsov, (US)

Correspondence Address: Vitaly Shchukin, Gasteiner Str. 13, Berlin, 10717, omitted

(21) Appl. No.: 11/808,011

(22) Filed: Jun. 6, 2007

Related U.S. Application Data
(60) Provisional application No. 60/814,054, filed on Jun. 16, 2006.

(51) Int. Cl. H01L 31/00

(52) U.S. Cl. 257/14

(57) ABSTRACT

A optoelectronic device is disclosed containing at least one multilayer interference reflector, having at least two periodicities in the refractive index. At least one of the periodicities, or quasi-periodicities, prohibits the light emission in a range of angles tilted with respect to the intentionally selected direction, for example, in the direction perpendicular to the layer planes, preventing the emission of light in the optical modes propagating in a certain interval of angles, dangerous for the device, and thus reducing the effect of parasitic modes on the device performance. A light generating element emitting light in a certain wavelength range is preferably introduced in one of the layers. The light is then channeled into the required angle range. The device can additionally contain a cavity. A second periodicity of the refractive index is preferably selected to ensure a high reflectivity in the vertical direction enabling advanced vertical cavity surface-emitting lasers.

In other embodiments a double periodicity is selected to ensure a high reflectivity of light in a direction tilted with respect to the vertical direction. An optoelectronic device having a multilayer interference reflector with two periodicities can operate as a light-emitting diode, a superluminescence light-emitting diode, a laser diode, a single photon emitter, or an emitter of entangled photons.

### REFERENCE TO RELATED APPLICATIONS

This application claims an invention which was disclosed in Provisional Application No. 60/814,054, filed Jun. 16, 2006, entitled “RESONANT CAVITY OPTOELECTRONIC DEVICE WITH SUPPRESSED PARASITIC MODES”. The benefit under 35 USC § 119(e) of the United States provisional application is hereby claimed, and the aforementioned application is hereby incorporated herein by reference.

### BACKGROUND OF THE INVENTION

1. Field of the Invention

The invention pertains to the field of semiconductor devices. More particularly, the invention pertains to ultrahigh-speed optoelectronic devices, such as light-emitting diodes and laser diodes

2. Description of Related Art

Optoelectronic devices are broadly applied in modern datacommunication, telecommunication, optical storage, display and lighting systems. These devices usually require directional light extraction from the device with power concentration is a certain angle, as characterized by brightness of the device. The problem, however, is the fact that the active media used in devices does not provide any angle selectivity.

FIG. 1 shows schematically a semiconductor structure (300) incorporating a plane (336) of optical oscillators emitting light at a certain photon energy corresponding to a certain wavelength of light λ₀ in the vacuum. The plane (336) is placed within a cavity (330), which is sandwiched between a first semiconductor material (310) and a second semiconductor material (320). In a practical case, where both the first semiconductor material (310) and the second semiconductor material (320) are the same material, which is optically isotropic, which is the case for GaAs and most of other III-V semiconductor materials, the emission of such oscillators is isotropic and the light propagates (345) in all directions. If the semiconductor structure (300) is epitaxially grown on a substrate, and further comprises contacts, the emitted light may be absorbed or scattered in the substrate and bottom contact regions, undergoes a total internal reflection at the semiconductor-air interface. Thus, without additional efforts like surface patterning, the external efficiency approaches only 3% for 100% of the internal (quantum) efficiency. Thus, a conventional light-emitting diode, in which the active region, which may be considered as one or a few plane of optical oscillators, is placed within a bulk material, has a very low efficiency.

The problem originates from the fact that there are many parasitic modes apart from the optical modes desired for the light emission. The problem may be solved if the parasitic modes are suppressed.

FIG. 2(a) shows a schematic diagram of a prior art of an all-epitaxial optoelectronic device, namely an edge-emitting device. The active region is placed in a waveguide region clad by the two layers having a lower refractive index and providing total internal reflection for the waveguiding mode. The device includes a substrate, a buffer layer, bottom cladding layer a waveguide layer with the active medium inserted, a top cladding layer, contact layer and metal contacts.

The laser structure (100) is grown epitaxially on an n-doped substrate (101). The structure further includes an n-doped cladding layer (102), a waveguide (103), a p-doped cladding layer (108), and a p-contact layer (109). The waveguide (103) includes an n-doped layer (104), a confinement layer (105) with an active region (106) inside the confinement layer, and a p-doped layer (107). The n-contact (111) is contiguous with the substrate (101). A p-contact (112) is mounted on the p-contact layer (109). The active region (106) generates light when a forward bias (113) is applied. The profile of the optical mode in the vertical direction z is determined by the refractive index profile in the z-direction. The refractive index of the waveguide (103) is preferably higher than the refractive index of the n-doped cladding layer (102) and of the p-doped cladding layer (108). The refractive index profile preferably ensures a single optical mode confined within the waveguide (103). Light in the optical mode undergoes the total internal reflection of the boundary between the waveguide (103) and the n-doped cladding layer (102) and on the boundary between the waveguide (103) and the p-doped cladding layer (108). Thus, light emitted in the optical mode confined in the waveguide (103) and propagates along the waveguide (103).

The waveguide (103) is bounded in the lateral plane by a front facet (116) and a rear facet (117). Light propagating in the confined optical mode can come out through the front facet (116) and through the rear facet (117). If a special highly reflecting coating is put on the rear facet (117), the laser light (115) is emitted only through the front facet (116).

The substrate (101) is formed from any III-V semiconductor material or III-V semiconductor alloy. For example, GaAs, InP, GaSb, GaP or InP are generally used depending on the desired emitted wavelength of laser radiation. Alternatively, sapphire, SiC or [111]-Si is used as a substrate for GaN-based lasers, i.e. laser structures, the layers of which are formed of GaN, AlN, InN, or alloys of these materials. The substrate (101) is doped by an n-type, or donor impurity. Possible donor impurities include, but are not limited to S, Se, Te, and amphoteric impurities like Si, Ge, Sn, where the latter are introduced under such technological conditions that they are incorporated predominantly into the cation sublattice to serve as donor impurities.

The n-doped cladding layer (102) is formed from a material lattice-matched or nearly lattice-matched to the substrate (101), is transparent to the generated light, and is doped by a donor impurity. In the case of a GaAs substrate (101), the n-doped cladding layer is preferably formed of a GaAlAs alloy.

The n-doped layer (104) of the waveguide (103) is formed from a material lattice-matched or nearly lattice-matched to the substrate (101), is transparent to the generated light, and is doped by a donor impurity. In the case of a GaAs substrate, the n-doped layer (104) of the waveguide is preferably formed of GaAs or of a GaAlAs alloy having an Al content lower than that in the n-doped cladding layer (102).

The p-doped layer (107) of the waveguide (103) is formed from a material lattice-matched or nearly lattice-matched to the substrate (101), is transparent to the generated light, and is doped by an acceptor impurity. Preferably, the p-doped layer (107) of the waveguide is formed from the same material as the n-doped layer (104) but doped by an acceptor impurity. Possible acceptor impurities include, but are not limited to, Be, Mg, Zn, Cd, Pb, Mn and amphoteric impurities like Si, Ge, Sn, where the latter are introduced under such technological conditions that they are incorporated predominantly into the anion sublattice and serve as acceptor impurities.

The p-doped cladding layer (108) is formed from a material lattice-matched or nearly lattice-matched to the substrate (101), transparent to the generated light, and doped by an acceptor impurity. Preferably, the p-doped cladding layer (108) is formed from the same material as the n-doped cladding layer (102), but is doped by an acceptor impurity.

The p-contact layer (109) is preferably formed from a material lattice-matched or nearly lattice matched to the substrate, is transparent to the generated light, and is doped by an acceptor impurity. The doping level is preferably higher than that in the p-cladding layer (108).

The metal contacts (111) and (112) are preferably formed from the multi-layered metal structures. The metal contact (111) is preferably formed from a structure including, but not limited to the structure Ni—Au—Ge. Metal contacts (112) are preferably formed from a structure including, but not limited to, the structure Ti—Pt—Au.

The confinement layer (105) is formed from a material lattice-matched or nearly lattice-matched to the substrate (101), is transparent to the generated light, and is either undoped or weakly doped. The confinement layers are preferably formed from the same material as the substrate (101).

The active region (106) placed within the confinement layer (105) is preferably formed by any insertion, the energy band gap of which is narrower than that of the energy band gap of the bottom cladding layer (102), of the n-doped layer (104) of the waveguide (103), of the confinement layer (105) of the waveguide (103), of the p-doped layer (107) of the waveguide (103), and of the top cladding layer (108). Possible active regions (106) include, but are not limited to, a single-layer or a multi-layer system of quantum wells, quantum wires, quantum dots, or any combination thereof. In the case of a device on a GaAs-substrate, examples of the active region (106) include, but are not limited to, a system of insertions of InAs, In₁₋ₓGaₓAs, InₓGa_{1-x-y}Al_{y}As, InₓGa₁₋ₓAs_{1-y}N_{y} or similar materials.

The disadvantage of this design is that below the lasing threshold, the emission of light occurs in all directions and only about 40% of the optical power or less is concentrated in the waveguiding mode. This happens because there are many parasitic modes that can have significant overlap with the active region. These modes deplete the gain spectrum.

FIG. 2(b) shows a schematic diagram of a prior art vertical cavity surface-emitting device. The active region is placed in a vertical cavity region clad by two multilayer interference reflectors; most often, distributed Bragg reflectors. The device includes a substrate, a buffer layer, a first distributed Bragg reflector, a cavity, a second distributed Bragg reflector. Metal contacts can be introduced, proton bombardment and (or) selective oxidation of the aperture region can be used to define the current path.

FIG. 2(b) shows schematically a prior art surface-emitting laser, particularly, a vertical cavity surface-emitting laser (VCSEL) (120). The active region (126) is put into a cavity (123), which is sandwiched between an n-doped bottom mirror (122) and a p-doped top mirror (128). The cavity (123) includes an n-doped layer (124), a confinement layer (125), and a p-doped layer (127). Bragg reflectors each including a periodic sequence of alternating layers having low and high refractive indices are used as a bottom mirror (122) and a top mirror (128). The active region (126) generates light when a forward bias (113) is applied. Light comes out (135) through the optical aperture (132). The wavelength of the emitted laser light from the VCSEL is determined by the length of the cavity (123).

The layers forming the bottom mirror (122) are formed from materials lattice-matched or nearly lattice matched to the substrate (101), are transparent to the generated light, are doped by a donor impurity, and have alternating high and low refractive indices. For a VCSEL grown on a GaAs substrate, alternating layers of GaAs and GaAlAs or layers of GaAlAs having alternating aluminum content preferably form the mirror (122).

The n-doped layer (124) of the cavity (123) is formed from a material lattice-matched or nearly lattice-matched to the substrate (101), is transparent to the generated light, and is doped by a donor impurity.

The p-doped layer (127) of the cavity (123) is formed from a material lattice-matched or nearly lattice-matched to the substrate (101), is transparent to the generated light, and is doped by an acceptor impurity.

The layers forming the top mirror (128) are formed from materials lattice-matched or nearly lattice-matched to the substrate (101), are transparent to the generated light, are doped by an acceptor impurity, and have alternating high and low refractive indices. For a VCSEL grown on a GaAs substrate, alternating layers of GaAs and GaAlAs or layers of GaAlAs having alternating aluminum content preferably form the mirror (128).

A metamorphic buffer grown on a lattice-mismatched substrate can be used as an effective substrate lattice-matched or nearly lattice-matched to most of the epitaxial layers forming the device (120).

The p-contact layer (129) is formed from a material doped by an acceptor impurity. For a VCSEL grown on a GaAs substrate, the preferred material is GaAs. The doping level is preferably higher than that in the top mirror (128). The p-contact layer (129) and the metal p-contact (112) are etched to form an optical aperture (132).

The confinement layer (125) is formed from a material lattice-matched or nearly lattice-matched to the substrate (101), is transparent to the generated light, and is either undoped or weakly doped. The confinement layers are preferably formed from the same material as the substrate (101).

The active region (126) placed within the confinement layer (125) is preferably formed by any insertion, the energy band gap of which is narrower than that of the bottom mirror (122), of the n-doped layer (124) of the cavity (123), of the confinement layer (125) of the cavity (123), of the p-doped layer (127) of the cavity (123), and of the top mirror (128). Possible active regions (126) include, but are not limited to, a single-layer or a multi-layer system of quantum wells, quantum wires, quantum dots, or any combination thereof. In the case of a device on a GaAs-substrate, examples of the active region (126) include, but are not limited to, a system of insertions of InAs, In₁₋ₓGaₓAs, In₁₋ₓGaₓAs, InₓGa_{1-x-y}Al_{y}As, InₓGa₁₋ₓAs_{1-y}N_{y} or similar materials.

The active region (126) generates optical gain when a forward bias (113) is applied. The active region (126) then emits light, which is bounced between the bottom mirror (122) and the top mirror (128). The mirrors have high reflectivity for light propagating in the normal direction to the p-n junction plane, and the reflectivity of the bottom mirror (122) is higher than that of the top mirror (128). Thus, the VCSEL design provides a positive feedback for light propagating in the vertical direction and finally results in lasing. The laser light (135) comes out through the optical aperture (132).

The device (120) has a broad spectrum of parasitic modes and can suffer from the same problems as the edge-emitting laser (100).

FIG. 3 shows a schematic diagram of a device operating in the high-order mode, for example, tilted cavity laser device, invented by the inventors of the present invention in the US patent “TILTED CAVITY SEMICONDUCTOR LASER (TCSL) AND METHOD OF MAKING SAME”, U.S. Pat. No. 7,031,360 by N. Ledentsov and V. Shchikin, filed Feb. 12, 2002, issued Aug. 18, 2006, and in the US patent application “TILTED CAVITY SEMICONDUCTOR OPTOELECTRONIC DEVICE AND METHOD OF MAKING SAME, U.S. patent application Ser. No. 10/943,044 by N. Ledentsov and V. Shchukin, filed Sep. 16, 2004. Both are incorporated here by reference.

The tilted cavity laser (200) shown in FIG. 3 is grown epitaxially on an n-doped substrate (101) and includes an n-doped bottom multilayered interference reflector (MIR) (202), a cavity (203), a p-doped top multilayered interference reflector (208), and a p-contact layer (209). The cavity (203) includes an n-doped layer (204), a confinement layer (205), and a p-doped layer (207). The confinement layer (205) further includes an active region (206). The laser structure (200) is bounded in the lateral plane by a rear facet (217) and a front facet (216). The cavity (203) and the multilayered interference reflectors (202) and (208) are designed such that resonant conditions for the cavity and for multilayered interference reflectors are met for only one tilted optical mode (220), the light propagating at a certain tilt angle and having a certain wavelength. If the rear facet (217) is covered by a highly reflecting coating, the output laser light (215) comes out only through the front facet (216). The resonant conditions to determine the optimum tilted optical mode (220) are met as follows. The cavity (203) has a first dispersion relation that defines the wavelength of the tilted optical mode as a function of the tilt angle. Each of the two MIRs, the bottom MIR (202) and the top MIR (208), has a dispersion relations that defines the wavelength of the stopband maximum in the reflectivity spectrum of the MIR for a tilt incidence of light as a function of the tilt angle of incidence. The dispersion relations in the cavity (203), on the one hand, and in the MIRs (202) and (208), on the other hand, are different. These dispersion relations match preferably at one wavelength and, correspondingly, one angle. At this wavelength and this angle, the optical mode confined in the cavity (203) is strongly reflected by the bottom MIR (202) and the top MIR (208) and exhibit small leakage loss. This wavelength is an optimum wavelength. At wavelengths, different from the optimum wavelength, the dispersion relations do not match any longer, the optical mode, confined in the cavity (203) is only weakly reflected by at least one MIR, either by the bottom MIR (202), or the top MIR (208), or both. Then the optical mode has a large leakage loss to the substrate and/or the contacts. In this case wavelength-stabilized device, or a tilted cavity laser or light-emitting diode is realized. The device may be surface-emitting, edge-emitting or provide an option for near-field outcoupling.

In this approach, minimum loss occurs for only one mode at only one wavelength. However, no suppression of parasitic modes at this wavelength is provided. The device may have many parasitic modes, and only a small part of emission comes to a desirable range of angles unless special design measures are undertaken.

Thus, all these prior art device, operating as diode lasers, may operate in a single optical mode and have a sufficient directionality. However, here certain problems may arise. The device may have many parasitic modes, and only a small part of emission comes to a desirable range of angles. Another disadvantage is the fact that below lasing threshold parasitic radiative losses increase threshold current and, being reabsorbed in different parts of the device cause significant overheating. In a different approach, a surface of the device is patterned in a 3D pattern preventing the light propagation in a broad range of angles, while selecting only the emission with desirable angle and wavelength. This approach utilizes laterally-processed photonic crystal structures. The disadvantage of this approach is the necessity of etching, which increases costs, reduces heat conductivity and current spreading across the wafer. There is a need in all-epitaxial approaches to solve the problem.

### SUMMARY OF THE INVENTION

A optoelectronic device is disclosed containing at least one multilayer interference reflector, having at least two periodicities in the refractive index. At least one of the periodicities, or quasi-periodicities, prohibits the light emission in a range of angles tilted with respect to the intentionally selected direction, for example, in the direction perpendicular to the layer planes, preventing the emission of light in the optical modes propagating in a certain interval of angles, dangerous for the device, and thus reducing the effect of parasitic modes on the device performance. A light generating element emitting light in a certain wavelength range is preferably introduced in one of the layers. The light is then channeled into the required angle range. The device can additionally contain a cavity. A second periodicity of the refractive index is preferably selected to ensure a high reflectivity in the vertical direction enabling advanced vertical cavity surface-emitting lasers.

In other embodiments a double periodicity is selected to ensure a high reflectivity of light in a direction tilted with respect to the vertical direction. An optoelectronic device having a multilayer interference reflector with two periodicities can operate as a light-emitting diode, a superluminescence light-emitting diode, a laser diode, a single photon emitter, or an emitter of entangled photons.

### BRIEF DESCRIPTION OF THE DRAWINGS

FIG. 1 shows schematically a semiconductor structure incorporating a plane of optical oscillators emitting at certain wavelength of light in vacuum or in an isotropic medium. The emission of such oscillators is isotropic.

FIG. 2(a) shows a schematic diagram of a prior art edge-emitting device.

FIG. 2(b) shows a schematic diagram of a prior art vertical-cavity surface-emitting device.

FIG. 3 shows a schematic diagram of a device operating in the high-order mode, for example, tilted cavity laser device.

FIG. 4(a) shows schematically an optical oscillator emitting light with a certain photon energy corresponding to a certain wavelength of light in the vacuum λ₀, wherein the optical oscillator is inserted into a medium with modulated refractive index, such that the emission in some directions is allowed, whereas the emission in some other direction is forbidden.

FIG. 4(b) shows schematically a periodic layered structure, the prior art reflectivity spectra of which are given in FIGS. 4(c) through 4(f).

FIG. 4(c) through 4(f) shows prior art optical reflectivity spectra of a periodic layered structure as a function of angle of incidence of the light from the reference medium. FIG. 4(c) shows the optical reflectance spectrum of the periodic layered structure of FIG. 4(b) at the angle of incidence of the light θ=65⁰. The selected wavelength of light λ₀ appears to be in the center of the reflectivity stopband at this angle.

FIG. 4(d) shows the prior art optical reflectivity spectrum of the periodic layered structure of FIG. 4(b) at the angle of incidence of the light θ=55⁰.

FIG. 4(e) shows the prior art optical reflectivity spectrum of the periodic layered structure of FIG. 4(b) at the angle of incidence of the light θ=40⁰.

FIG. 4(f) shows the prior art optical reflectivity spectrum of the periodic layered structure of FIG. 4(b) at the normal incidence of the light (θ=0⁰).

FIG. 5 shows a schematic diagram of the emission distribution in the prior art device of FIG. 1(b).

FIG. 6(a) shows a schematic diagram of the device of FIG. 1(b) in respect to the three groups of emission: vertical cavity emission, in-plane waveguiding emission and the tilted emission.

FIG. 6(b) shows a schematic diagram of the mode intensity distribution in the device with a guiding cavity.

FIG. 6(c) shows a schematic diagram of the mode intensity distribution in the device with an anti-guiding cavity.

FIG. 7 shows schematically optical field distribution in one of the tilted modes of FIG. 6(b) having the strongest intensity in the active region. One can see, in particular, that this mode has an intensity maximum in the active region. For the tilted modes having a low intensity in the active zone the confinement factor is small and the related emission is weak. Thus, it is only a certain range of angles causing the most of the parasitic radiative losses.

FIG. 8 shows schematically a device, according to one embodiment of the present invention. The DBRs in the device have two periodicities. The first periodicity provides VCSEL DBRs to support vertical lasing and the second periodicity provides a stopband for emission of light in the relevant angle range.

FIG. 9(a) shows schematically refractive index profile a single-periodicity DBR in a standard prior-art VCSEL device.

FIG. 9(b) shows schematically refractive index profile a double-periodicity DBR in a device, according to one of the embodiment of the present invention, wherein the second periodicity is realized by increasing the refractive index of the low-refractive index component. The double periodicity illustrated in FIG. 9(b) provides a coarse-scale period, comprising eight fine-scale layer pairs. Four layer pairs out of eight form a so called periodicity 1, and the rest four layer pairs out of eight form a so called periodicity 2.

FIG. 9(c) shows schematically refractive index profile a double-periodicity DBR in a device, according to one another of the embodiment of the present invention, wherein the second periodicity is realized by decreasing the refractive index of the high-refractive index component. The double periodicity illustrated in FIG. 9(c) provides a coarse-scale period, comprising eight fine-scale layer pairs. Four layer pairs out of eight form a so called periodicity 1, and the rest four layer pairs out of eight form a so called periodicity 2.

FIG. 9(d) shows schematically refractive index profile a double-periodicity DBR in a device, according to yet another embodiment of the embodiment of the present invention, wherein the second periodicity is realized by changing the relative thickness in the DBR keeping the same fine-scale periodicity. The double periodicity illustrated in FIG. 9(c) provides a coarse-scale period, comprising eight fine-scale layer pairs. Four layer pairs out of eight form a so called periodicity 1, and the rest four layer pairs out of eight form a so called periodicity 2.

FIG. 10 shows a schematic diagram of a device, according to a further embodiment of the present invention, wherein an additional part of the bottom distributed Bragg reflector (DBR) is added to the device of the embodiment of FIG. 8, wherein the additional part of the DBR has a different refractive index profile compared with the DBR of the embodiment of FIG. 8.

FIG. 11 shows a schematic diagram of a device, according to one another embodiment of the present invention, wherein the device is optimized for tilted emission of the allowed component of light.

FIG. 12 shows a schematic diagram of a device, according to yet another embodiment of the present invention, wherein a single periodicity of the DBRs prohibits parasitic radiative losses at large tilted angles.

FIG. 13 shows a schematic diagram of a device, according to a further embodiment of the present invention, wherein the double periodicity of the multilayer interference reflector is optimized for in-plane light propagation and prohibits the emission in vertical and tilted directions.

FIG. 14 shows a schematic diagram of a device, according to one another embodiment of the present invention, wherein both DBRs have two periodicities, and one of the layers in each pair of layers in one of the periodicities is formed from GaAlAs or AlAs and is further oxidized to form a partially oxidized layer of GaAlO or AlO.

FIG. 15 shows a schematic diagram of a device, according to yet another embodiment of the present invention, wherein a device of the embodiment of FIG. 14 is processed further such, that partially oxidized layers of GaAlO or AlO are etched thus forming air gaps.

FIG. 16 shows a schematic diagram of a device, according to a further embodiment of the present invention, wherein intracavity contacts are used, both DBRs have two periodicities, and one of the layers in each pair of layers in one of the periodicities is formed from GaAlAs or AlAs and is further oxidized to form a completely oxidized layer of GaAlO or AlO.

FIG. 17 shows a schematic diagram of a device according to one further embodiment of the present invention, wherein both DBRs have two periodicities, and one of the layers in each pair of layers in one of the periodicities is formed from GaAlAs or AlAs and is further oxidized to form a partially oxidized layer of GaAlO or AlO, the device is further processed such that the oxide layers are etched out forming air gaps, and wherein the processing is asymmetric, such that air gaps are formed also in the central part of the device.

### DETAILED DESCRIPTION OF THE INVENTION

The present invention provides a way to improve performance of light-emitting diodes, laser diodes, optical amplifiers and photodetectors by suppressing the undesirable radiative modes. The directionality, the efficiency and the modulation speed of the devices can be improved.

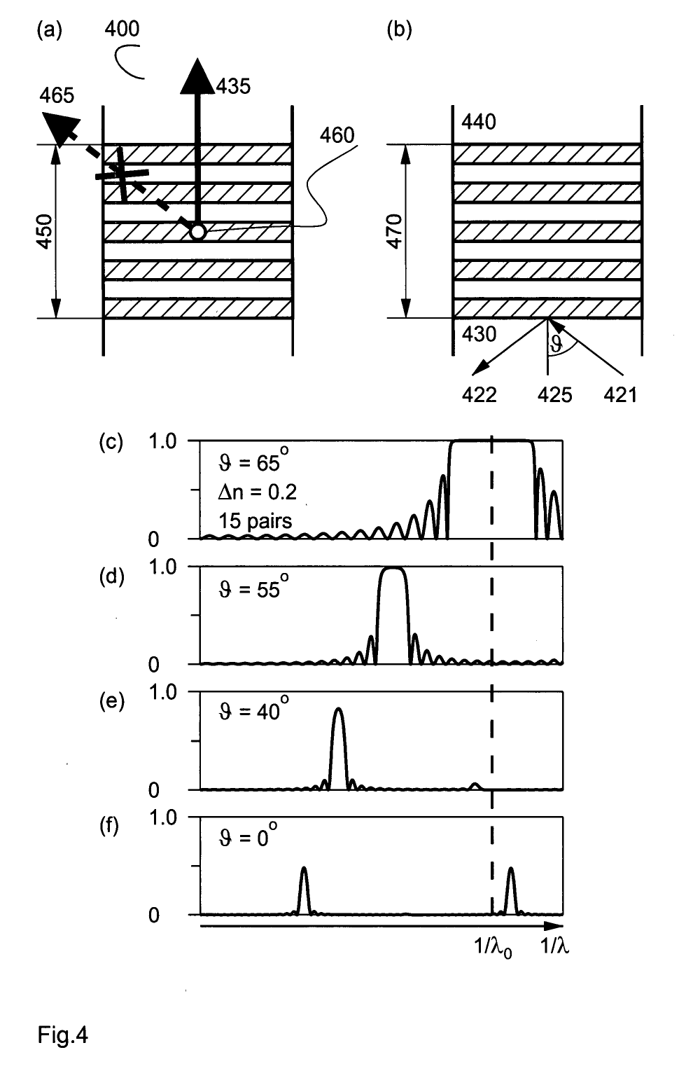

The basic approach to improve directionality at a certain wavelength is to place the source of the light in a multilayer epitaxial structure. FIG. 4(a) shows schematically a semiconductor structure (400), wherein an optical oscillator (460), emitting light having a certain photon energy which corresponds to the wavelength of light in the vacuum λ₀, is inserted into a medium (450) with modulated refractive index, i.e. into a multilayer structure. The multilayer structure (450) is selected such that light in some directions (435) exits the crystal with high probability, whereas light does not come out in some other directions (465).

FIGS. 4(b) through 4(f) illustrate the possibility to forbid transmission of light through a multilayer structure in some selected directions. FIG. 4(b) shows schematically a periodic multilayer structure (470) sandwiched between a first medium (430) and a second medium (440). Light (421) impinges on the periodic multilayer structure (470) at a tilt angle θ, is partially reflected back (422), and partially transmitted. The tilt angle θ is defined with respect to the direction (425), normal to the planes of the layers in the multilayer structure (470). FIGS. 4(c) through 4(f) show prior art calculated reflectivity spectra of a periodic multilayered structure for a few different tilt angles of the propagating TE electromagnetic wave, as described by A. Yariv and P. Yeh, in Optical Waves in Crystals. Propagation and Control of Laser Radiation, Wiley, 1984, Chapter 6, which is incorporated herein by reference. Light comes from the medium (430) with a refractive index n₁=3.6, and the structure includes 15 periods, each period further including one layer of the Λ/2 thickness having a low refractive index n₂=3.4 and one layer of equal Λ/2 thickness having a high refractive index n₁=3.6. The medium (440) behind the periodic structure (470) also has a refractive index n₁=3.6. The reflectivity is plotted as a function of 1/λ, where λ is the wavelength of the electromagnetic wave in the vacuum. FIGS. 4(c) through 4(f) reproduce the prior art figures by A. Yariv and P. Yeh (Optical Waves in Crystals. Propagation and Control of Laser Radiation, Wiley, 1984, Chapter 6), where the reflectivity spectra are plotted versus the frequency 0 of the electromagnetic wave, and ω=c/λ, where c is the speed of light in the vacuum.

The major properties of the reflectivity spectra of FIGS. 4(c) through 4(f) are as follows. At the normal incidence, θ=0, as shown in FIG. 4(f), the reflectivity spectrum reveals narrow spikes of a low amplitude. As the angle θ increases, spikes shift towards shorter wavelengths, the amplitude of the spikes increases, and the spikes become broader. This is seen in FIG. 4(e) for θ=40⁰ and in FIG. 4(d) for θ=55⁰. Broadened spikes with form stopbands with a reflectivity close to 1. This is seen in FIG. 4(d) for θ=55⁰, and, more pronounced, in FIG. 4(c) for θ=65⁰.

Let the selected wavelength λ₀ be in the center of the well pronounced stopband of the reflectivity spectrum of the multilayer structure (470) at the angle, say, θ=65⁰, as shown in FIG. 4(f). Then light at this wavelength is nearly completely reflected back, and the transmission of the light through this structure is nearly forbidden. Referring again to an oscillator (460) inserted in a multilayer structure (450), as shown in FIG. 4(a), one can note the following. Basic properties of multilayered structure persist also in the case, where the source of light, i.e. the optical oscillator (460) is inserted inside a multilayer structure. This implies that transmission of light through a multilayer structure can be forbidden in some directions, as shown in FIG. 4(a).

The idea to suppress certain most dangerous parasitic modes of the emitted light has earlier been applied for vertical cavity surface emitting lasers having an antiwaveguiding cavity. U.S. patent application Ser. No. 11/099,360, entitled “OPTOELECTRONIC DEVICE BASED ON AN ANTIWAVEGUIDING CAVITY”, filed Apr. 5, 2005, by the inventors of the present invention and incorporated herein by reference, discloses a semiconductor optoelectronic device comprising at least one cavity and one multilayered interference reflector. The cavity is designed preferably to possess properties of an antiwaveguiding cavity. The cavity has a lower refractive index as compared to the average refractive indices of the DBRs, thus the fundamental optical mode of the device is not localized in the cavity. No optical modes having a significant overlap with the active medium can propagate in the lateral plane. The existing optical modes are the modes propagating in the vertical direction or in a direction tilted to the vertical direction, such that the tilt angle smaller than the angle of the total internal reflection at the semiconductor-air interface and light in such optical modes can come out of the device through the top surface or the substrate. This design reduces the influence of parasitic optical modes and improves characteristics of optoelectronic devices including vertical cavity surface emitting laser, tilted cavity laser emitting through the top surface or a substrate, vertical or tilted cavity resonant photodetecor, vertical or tilted cavity resonant optical amplifier, light-emitting diode, and others. In this invention the most dangerous modes in vertical cavity surface-emitting lasers (VCSEL), which may propagate in-plane along the oxide aperture, so called whispering gallery modes, which may have a sufficient quality factor to result in significant stimulated emission amplification and the radiative lifetime shortening, are prohibited. The whispering gallery modes, which result from the outer VCSEL mesa boundary, and which have very high quality factor filling the mesa from the outside boundary to ˜R/n, where R is the outer mesa radius and n is the effective refractive index of the in-plane waveguide, also affect the device performance and may even cause lasing and self-pulsations if the ˜R/n is within the oxide-confined aperture of the device.

The problem, however, is that there can be also whispering gallery modes associated with the tilted vertical modes, which also can be dangerous.

A significant suppression of the lateral and tilted modes is possible without an antiwaveguiding design of the cavity, if the optical confinement factor of this mode in the active region is small. One possible embodiment includes a cavity, the refractive index of which is equal or close to the square root of the weighted average of the refractive index square of the DBRs. Another possible embodiment includes the active region placed to a position, where the field intensity of the parasitic modes is small, whereas the optical confinement factor of the active vertical cavity mode is sufficiently large.

In order to find the way to further suppress dangerous optical modes, the following note should be given. There are two issues affecting the probability of emitting light into a particular optical mode. In an optoelectronic device, electrons and holes recombine in an active region generating light. The probability of emitting light in a particular optical mode is governed by two factors. The first one refers to the overlap between the active medium and the optical field intensity for the particular mode. The second one refers to the overall possibility for the given mode with a certain angle of propagation of light to exist in the crystal. Once the active medium is placed in a uniform layer, the boundaries of which have a high reflectivity, there are optical modes which have maximum intensity in the active medium, and these modes will show the maximum emission rate. On the other hand, there other optical modes having nearly zero intensity in the active medium, and those modes will exhibit a negligible emission rate. Thus, these are only certain modes having a large overlap with the active medium. If these modes are prohibited by a properly selected multilayer interference reflector, no radiative losses become possible for the related parasitic emission, and the device performance can be dramatically improved.

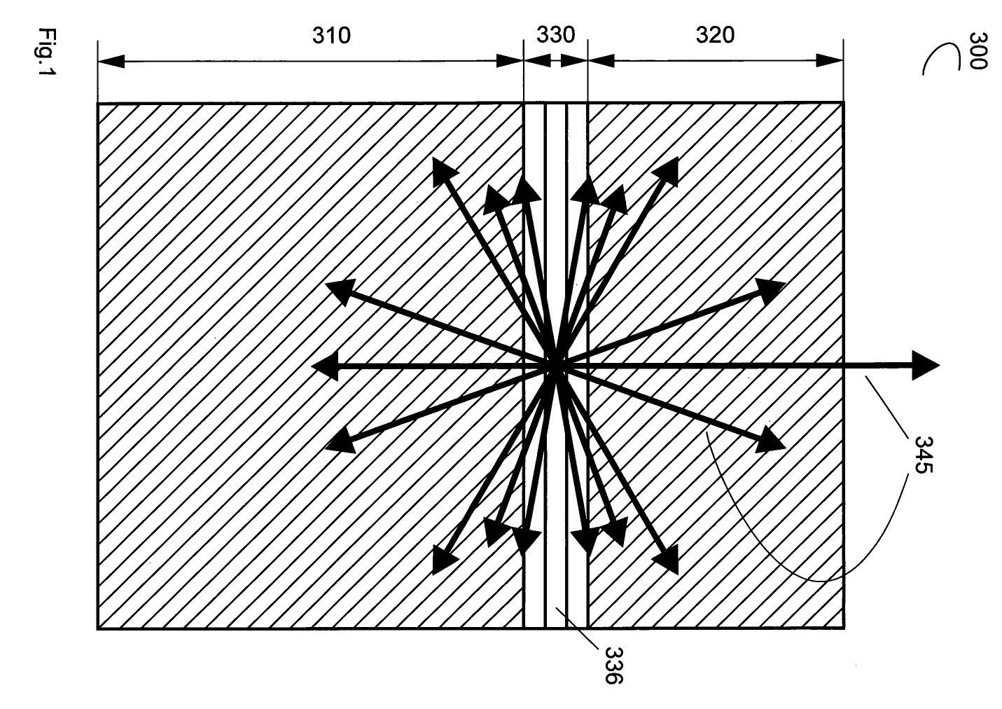

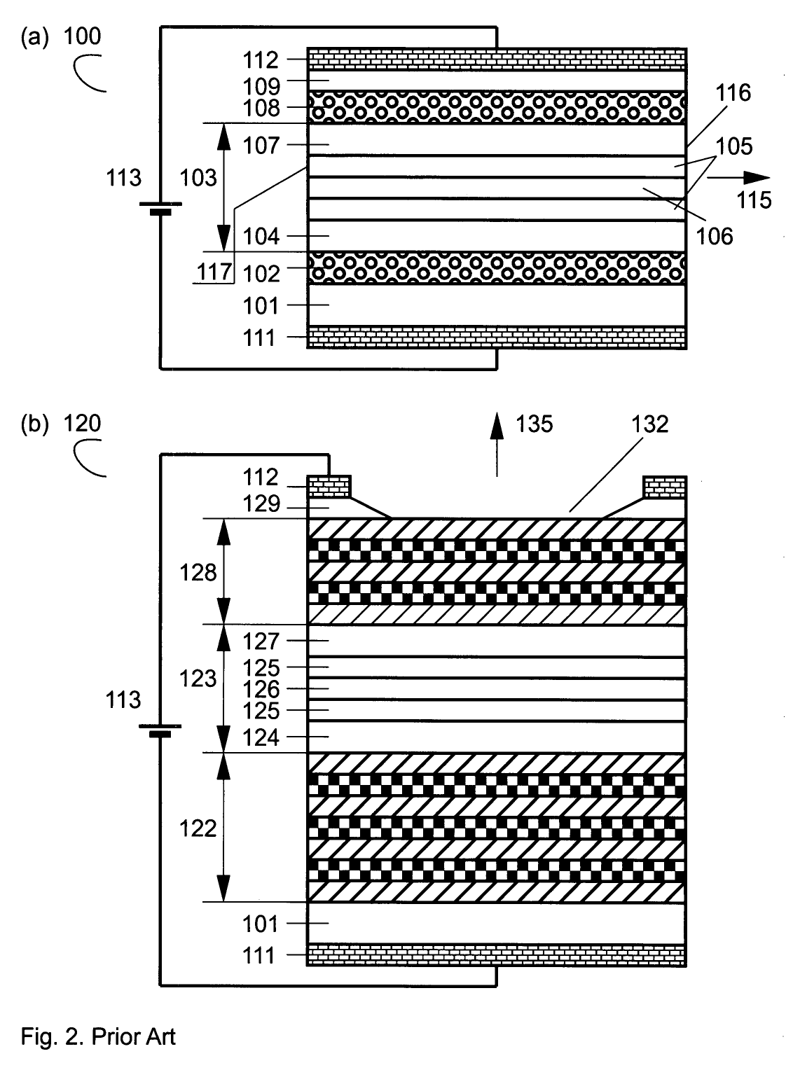

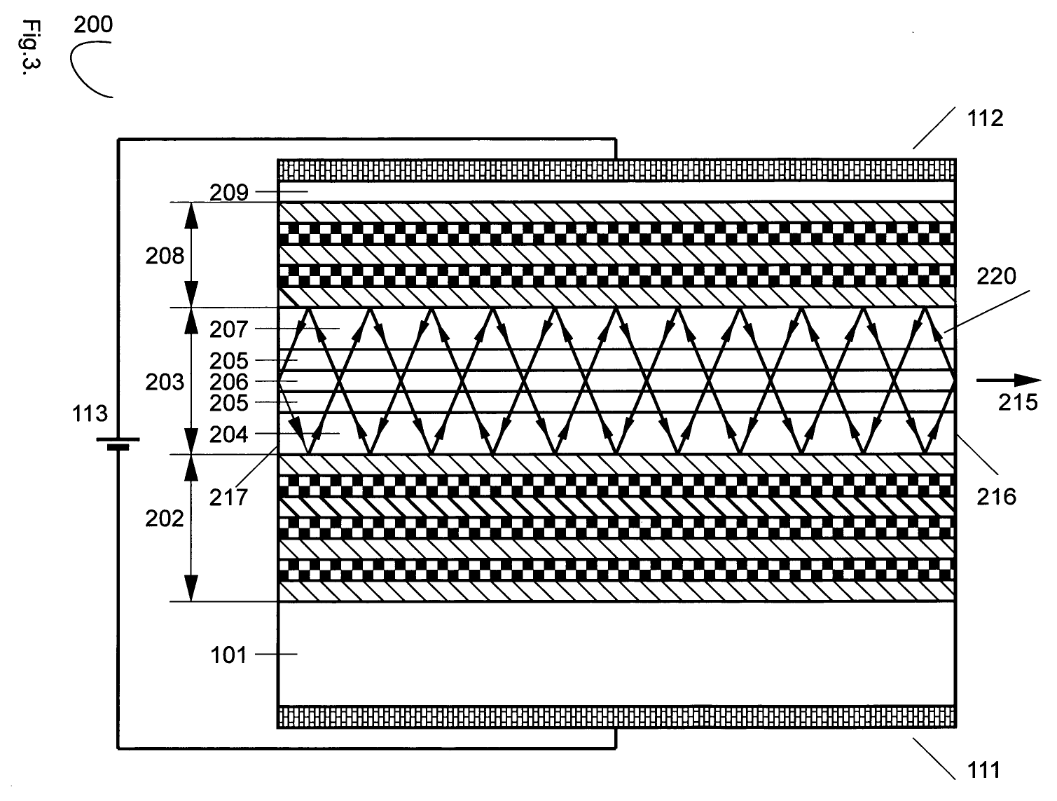

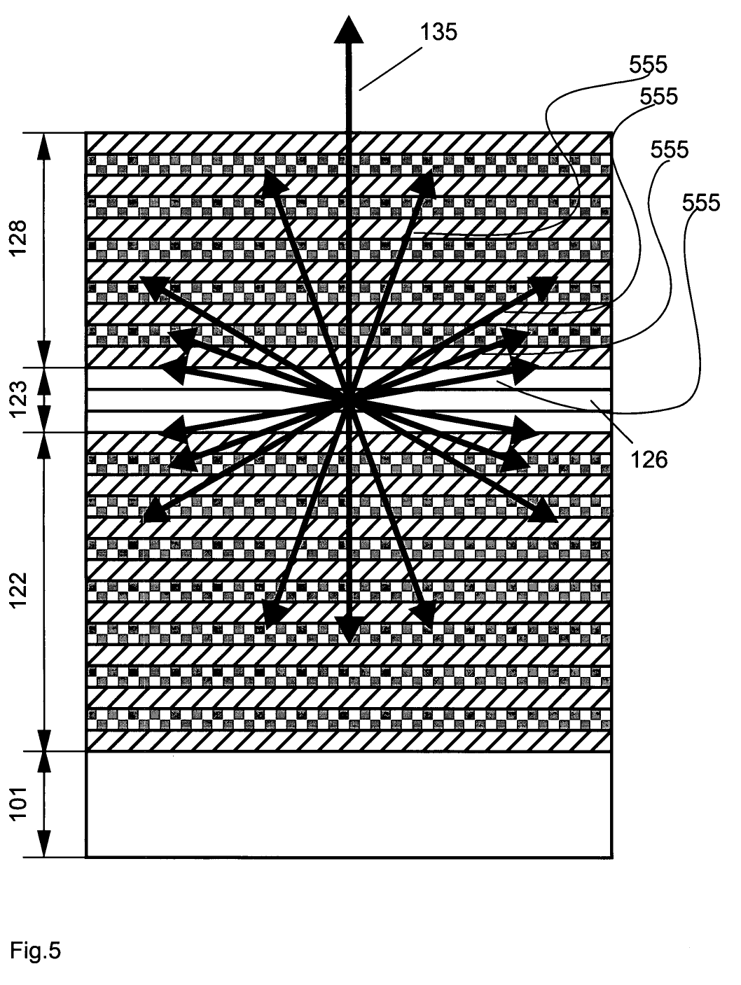

To find a way to suppress parasitic modes, it is worth considering the angular distribution of light emission, first from a prior art device. FIG. 5 shows a schematic diagram of the emission distribution in the prior device of FIG. 1(b). Apart of the light emission in the vertical optical mode (135), light is also emitted in many tilted optical modes (555). Thus, there are many radiative modes in a VCSEL and in resonant cavity devices, apart from the useful vertical or quasi-vertical mode.

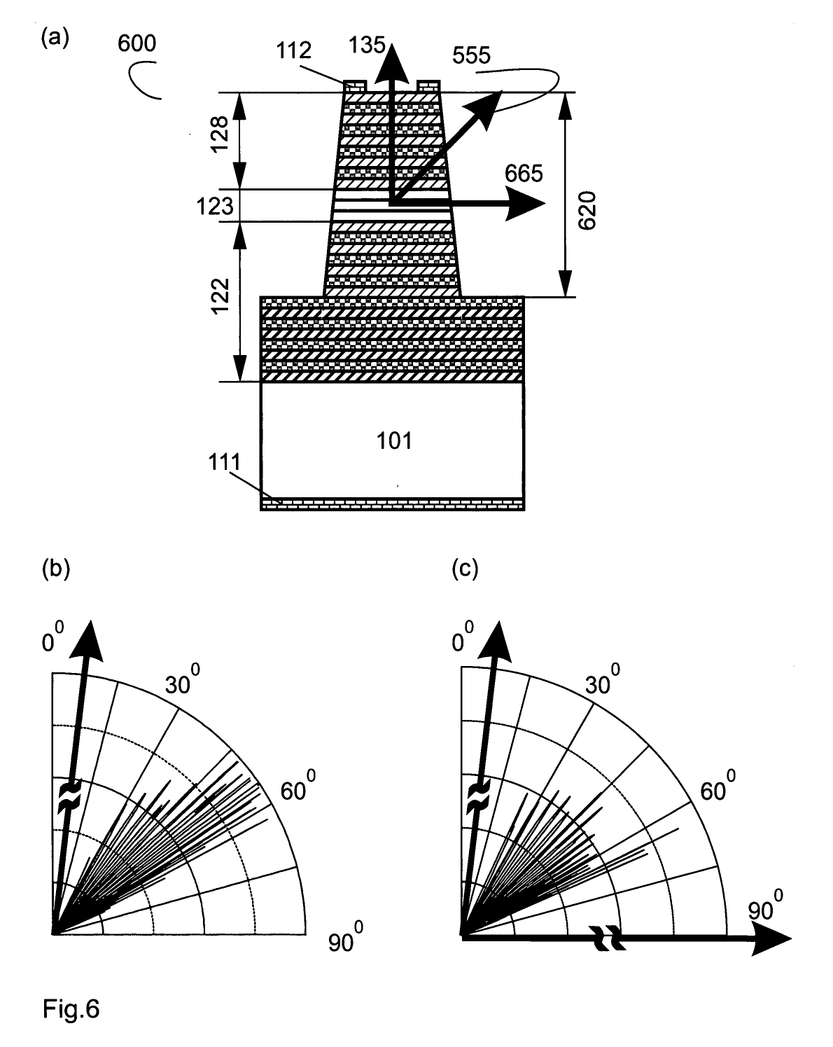

FIG. 6(a) shows a schematic diagram of a prior-art device of FIG. 1(b) with respect to the three groups of emission. The device (600) is processed in such a way that a mesa (620) is formed, as is preferably done for vertical cavity optoelectronic devices. Emission of light consists of three groups of optical modes: emission in the vertical cavity mode (135), emission in the in-plane waveguiding modes (665), and emission in the tilted modes (555).

FIG. 6(b) shows a schematic diagram of the mode intensity distribution in the device with an anti-waveguiding cavity. One can see that in this design most of the emitted light is directed in the directions tilted with respect to the surface and is lost for lasing. The important issue of FIG. 6(b) is the fact that the parasitic emission is predominantly concentrated in a relatively narrow range of angles, where the mode intensities overlap effectively with the active region.

FIG. 6(c) shows a schematic diagram of the mode intensity distribution in the device with a waveguiding cavity. In this case the relevance of the tilted modes is weaker, however, about 35-50% of the emission can be concentrated in the parasitic waveguiding mode, resulting in a lot of problems for the device due to formation of high finesse whispering gallery modes associated with oxide aperture or the outer diameter of the VCSEL mesa. Once population inversion is achieved the radiative recombination rate may be dramatically enhanced, depleting the gain and causing higher current densities to achieve vertical lasing, additional overheating and potentially, self-pulsation of the device and/or noise enhancement.

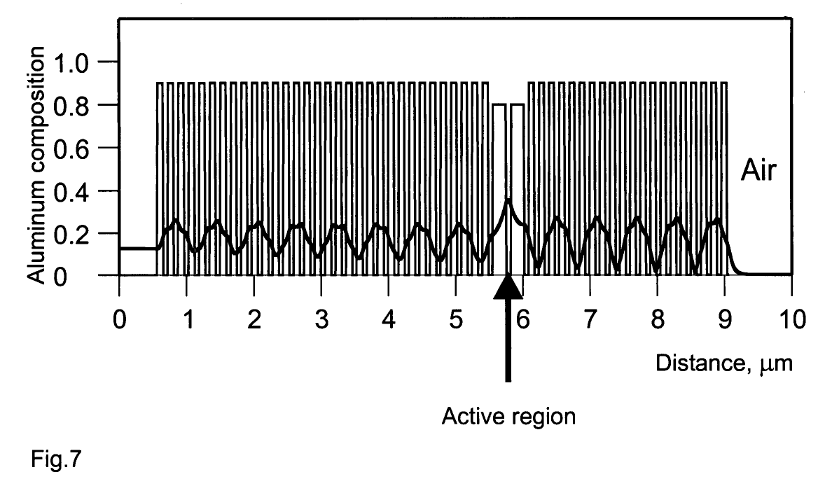

FIG. 7 shows schematically optical field distribution in one of the tilted modes of FIG. 6(b) having the strongest intensity in the active region. One can see that this mode has an intensity maximum in the active region. For the tilted modes having a low intensity in the active zone the confinement factor is small and the related emission is weak. Thus, it is only a certain range of angles causing most of the parasitic radiative losses. Once the modes having a significant overlap with the active region are suppressed, the radiative losses can be significantly reduced.

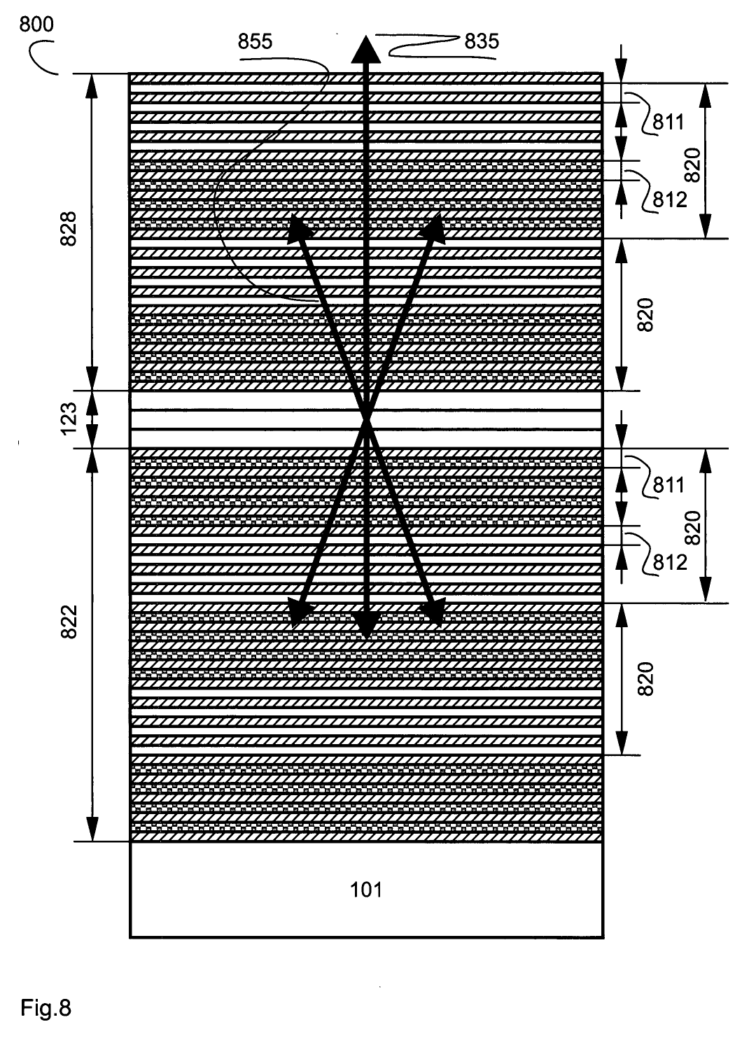

FIG. 8 shows schematically an optoelectronic device, according to a preferred embodiment of the present invention. The device (800) comprises a cavity (123) sandwiched between a bottom distributed Bragg reflector (DBR) (822) and a top DBR (828). Both the bottom DBR (822) and the top DBR (828) have two periodicities. In the embodiment of FIG. 8, the two periodicities are realized as follows. The bottom DBR (822) and the top DBR (828) comprise a coarse-scale period (820). Each coarse-scale period (820) comprise a few layer pairs (811) realizing a first periodicity and a few layer pairs (812) realizing a second periodicity. In the particular embodiment of FIG. 8, the first periodicity is realized by four layer pairs (811) and the second periodicity is realized by four layer pairs (812). The first periodicity provides VCSEL DBRs to support vertical lasing (835) and the second periodicity provides a stopband for radiative recombination with emission in the relevant angle range. Apart from the emission in the vertical mode (835), the device (800) can emit light in the tilted modes (855) in a narrow interval of angles close to the direction normal to the surface. The general layout and contact geometry of the device can be similar to that of prior art device of FIG. 1(b). Prohibition of the parasitic modes increases the efficiency of light extraction and the differential gain of the device.

In another embodiment of the present invention, only the top DBR has a double periodicity. And in yet another embodiment of the present invention, only the bottom DBR has a double periodicity.

The number of pairs forming first periodicity and second periodicity can be different from each other as well as be different from four. A preferred number of pairs in each of the periodicities forming a coarse scale period of the DBRs is between two and ten. One another embodiment of the present invention is possible, where one of the periodicities contain only one period. Thus, e.g., a coarse scale period can contain a few fine-scale periods corresponding to a first periodicity and one period corresponding to a second periodicity. And yet another embodiment of the present invention is possible, where a coarse scale period contain one period corresponding to a first periodicity and one period corresponding to a second periodicity.

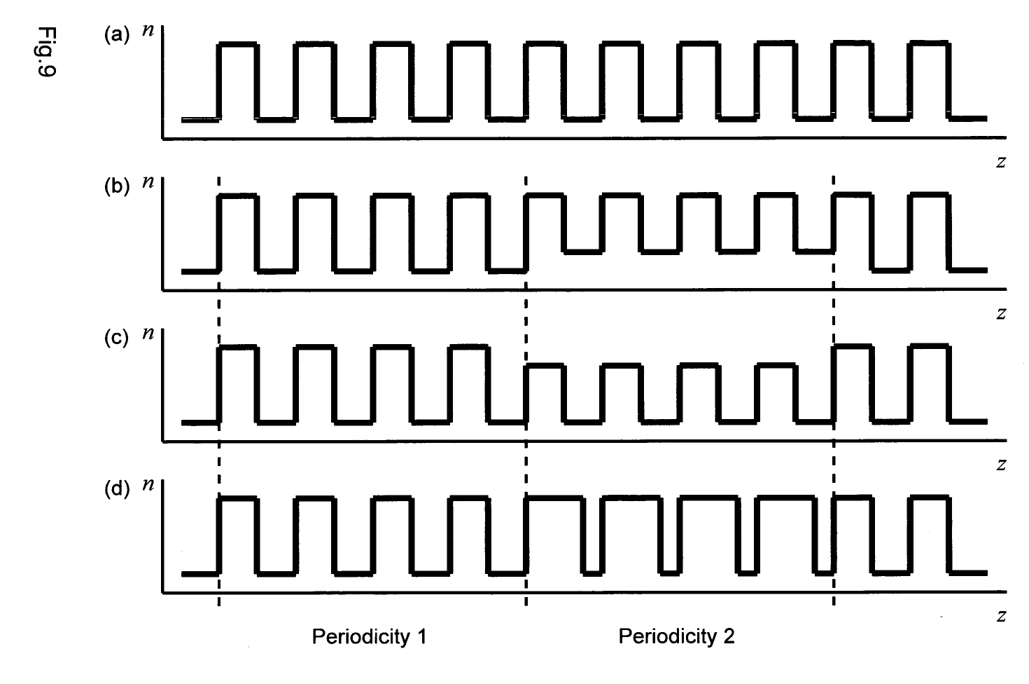

The double periodicity can be realized in different ways. FIG. 9 gives a few examples, which may be further extended. For comparison, FIG. 9 (a) shows schematically the refractive index profile of a single-periodicity DBR in the standard prior-art VCSEL device. FIG. 9(b) shows schematically the refractive index profile of a double-periodicity DBR in the device of the embodiment of FIG. 8, where the second periodicity is realized by increasing the refractive index of the low-refractive index layers. FIG. 9(c) shows schematically the refractive index profile of a double-periodicity DBR in the device of the embodiment of FIG. 8, where the second periodicity is realized by decreasing the refractive index of the high-refractive index layers. FIG. 9(d) shows schematically the refractive index profile of a double-periodicity DBR in the device of the embodiment of FIG. 8, where the second periodicity is realized by changing the relative thickness of the layers in the DBR keeping the same fine-scale periodicity.

Other embodiments of the present invention include triple or multiple periodicities in the DBRs.

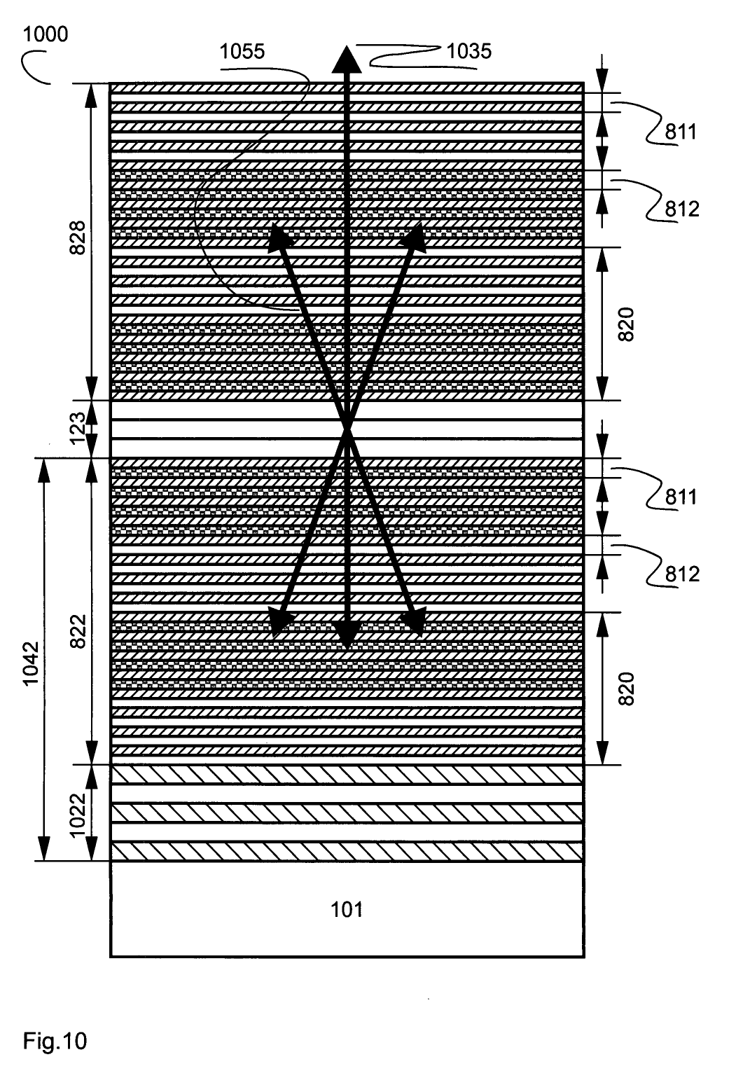

FIG. 10 shows a schematic diagram of an optoelectronic device (1000) according to one another embodiment of the present invention. In addition to the device shown in FIG. 8, the device (1000) comprises a bottom DBR (1042) further comprising a first section (822) having a double periodicity and a second section (1022) having a different refractive index profile. This part (1022) can be used for further suppression of the tilted modes, or, as opposite to ensuring high reflection of the vertical mode and can itself have double or multiple periodicities. The device (1000) is preferably selected to emit light in the vertical mode (1035) and in tilted modes (1055) in a narrow angle interval close to the direction normal to the surface.

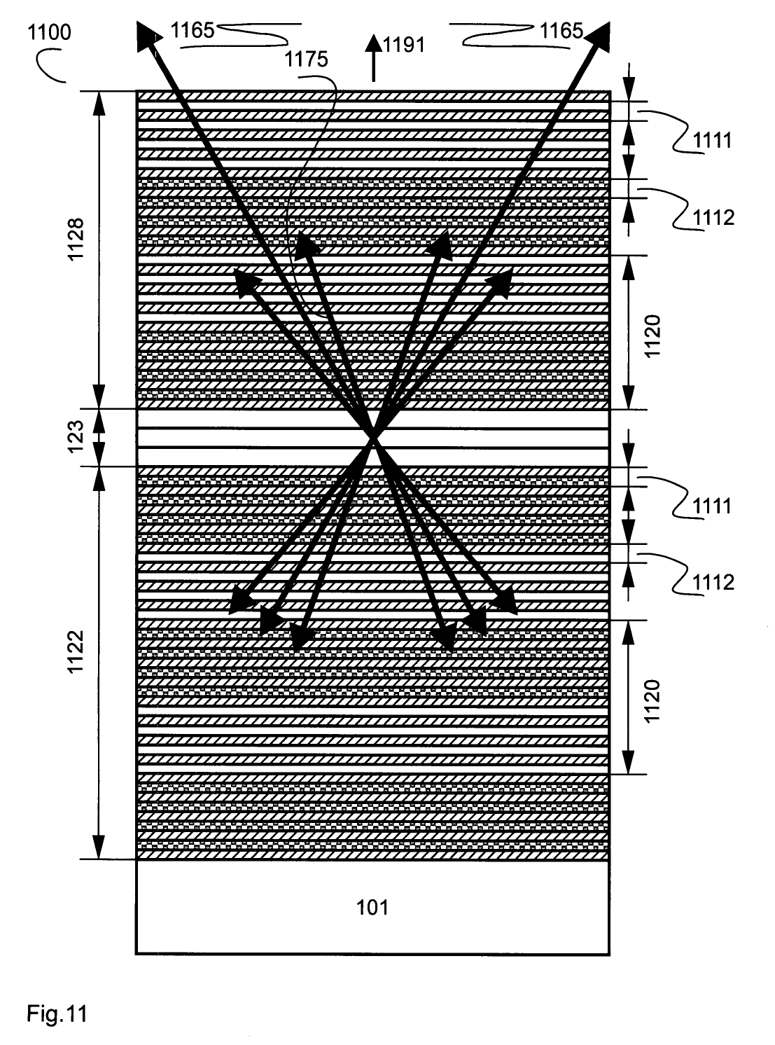

FIG. 11 shows a schematic diagram of an optoelectronic device (1100) according to yet another embodiment of the present invention. The device (1100) comprises a cavity (123) sandwiched between a bottom multilayer interference reflector (MIR) (1122) and a top MIR (1128). Both the bottom MIR (1122) and the top MIR (1128) have two periodicities. The two periodicities are realized as follows. Both the bottom MIR (1122) and the top MIR (1128) have a coarse-scale period (1120). Each coarse-scale period (1120) comprises a few layer pairs (1111) realizing a first periodicity and a few layer pairs (1112) realizing a second periodicity. In the particular embodiment (1100) shown in FIG. 11, the first periodicity is realized by four layer pairs (1111) and the second periodicity is realized by four layer pairs (1112). Both the first periodicity and the second periodicity are optimized for tilted emission of the allowed component (1165). Apart from the emission in the optimum direction (1165), emission occurs (1175) also in a certain interval of angles around the optimum direction. Such a design can be favorable for the device operating in a tilted cavity mode. If the emitted radiation has the maximum intensity in a direction tilted with respect to the direction (1191) normal to the surface plane, the emitted light has usually a multi-lobe pattern depending also on the shape of the optical aperture in the surface plane. If the optical aperture in the surface plane has a rectangular shape, the far-field pattern has two or four lobes tilted at the same polar angle with respect to the direction (1191) normal to the surface plane, but at different azimuths. If the optical aperture in the surface plane has a circular shape, the far field has preferably a conical shape corresponding to the emission of light at a certain polar angle and homogeneously distributed over all azimuths.

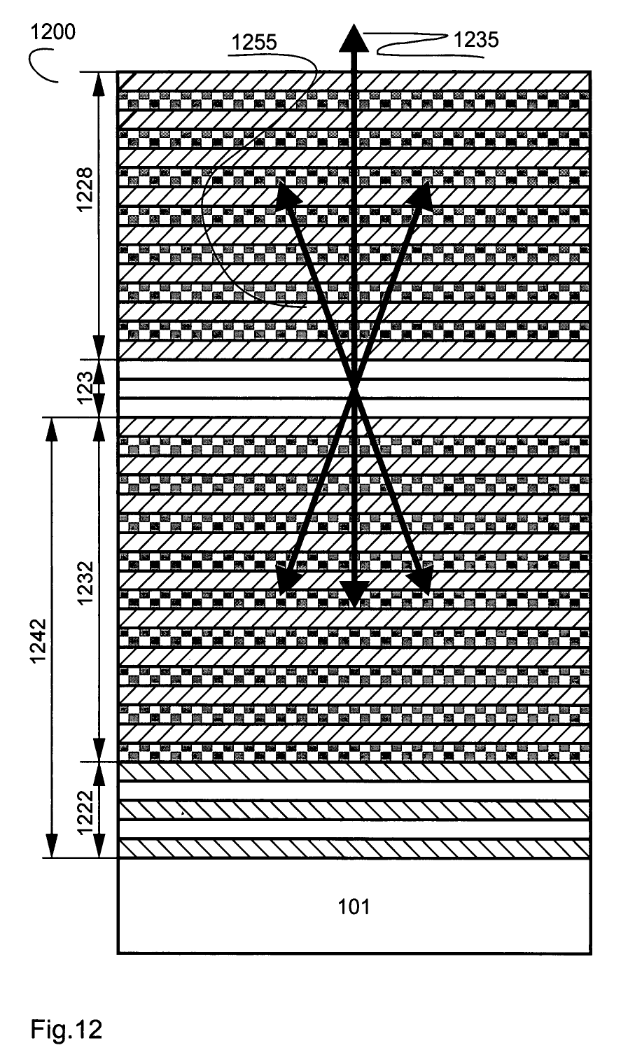

FIG. 12 shows a schematic diagram of an optoelectronic device (1200) according to a further embodiment of the present invention. The device (1200) comprises a cavity (123) sandwiched between a bottom DBR (1242) and a top DBR (1228). The bottom DBR (1242) further comprises a first part (1232) and a second part (1222). The first part (1232) of the bottom DBR (1242) has a single periodicity. The second part (1222) of the bottom DBR (1242) has also a single periodicity. The first part (1232) of the bottom DBR (1242) is selected such that it prohibits parasitic radiative losses at tilted angles. The additional, second part (1222) of the bottom DBR (1242) is used for ensuring high reflectivity of the optical mode propagating in the vertical reflection. The two parts of the bottom DBR (1242) can also be regarded as a different realization of a double periodicity. Light is emitted from the device (1200) in a vertical mode (1235). Some tilted modes (1255) are also emitted at small or moderate tilt angles with respect to the direction normal to the surface plane.

It will be appreciated by those skilled in the art that an optoelectronic device having a cavity sandwiched between two DBRs or MIRs, wherein at least one DBR or MIR has two periodicities, can be realized in different ways. In one further embodiment of the present invention the emission of light can occur through the substrate. In yet another embodiment of the present invention light can be extracted via near-field outcoupling. All possible modifications, however, serve the goal of suppressing parasitic tilted modes by applying a special structure with periodic or quasi-periodic refractive index profile.

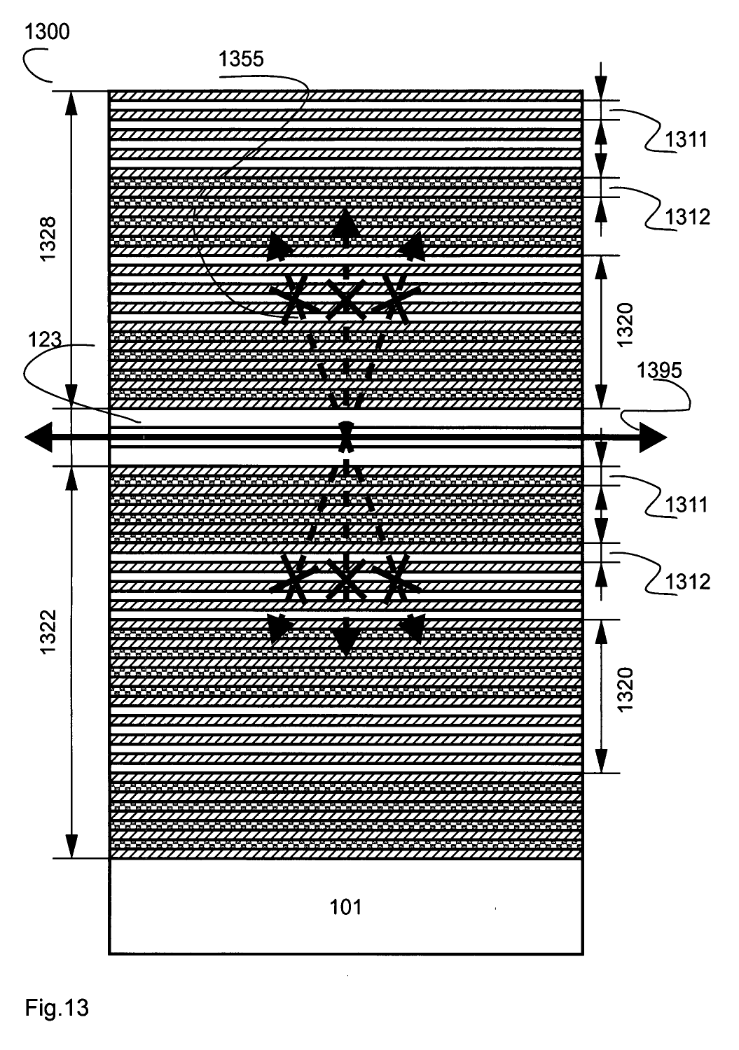

FIG. 13 shows a schematic diagram of an optoelectronic device (1300) according to one another embodiment of the present invention. The device (1300) comprises a cavity (123) sandwiched between a bottom multilayer interference reflector (MIR) (1322) and a top MIR (1328). Both the bottom MIR (1322) and the top MIR (1328) have two periodicities. The two periodicities are realized as follows. Both the bottom MIR (1322) and the top MIR (1328) have a coarse-scale period (1320). Each coarse-scale period (1320) comprises a few layer pairs (1311) realizing a first periodicity and a few layer pairs (1312) realizing a second periodicity. In the particular embodiment (1300) shown in FIG. 13, the first periodicity is realized by four layer pairs (1311) and the second periodicity is realized by four layer pairs (1312). The double periodicity of the multilayer interference reflectors is optimized for in-plane propagation and prohibiting the emission in vertical and tilted directions. Thus, emission in both vertical direction and tilted (1355) directions is suppressed, and emission occurs only in the in-plane optical mode (1395). The suppression of both vertical and tilted modes is very advantageous for edge emitting devices, such as edge-emitting laser diodes and may lead to significant improvement in threshold current, temperature stability and differential gain.

Further embodiment of the present invention includes an edge-emitting distributed feedback laser. And another embodiment of the present invention is an optoelectronic device operating as a multi-sectional edge-emitting laser.

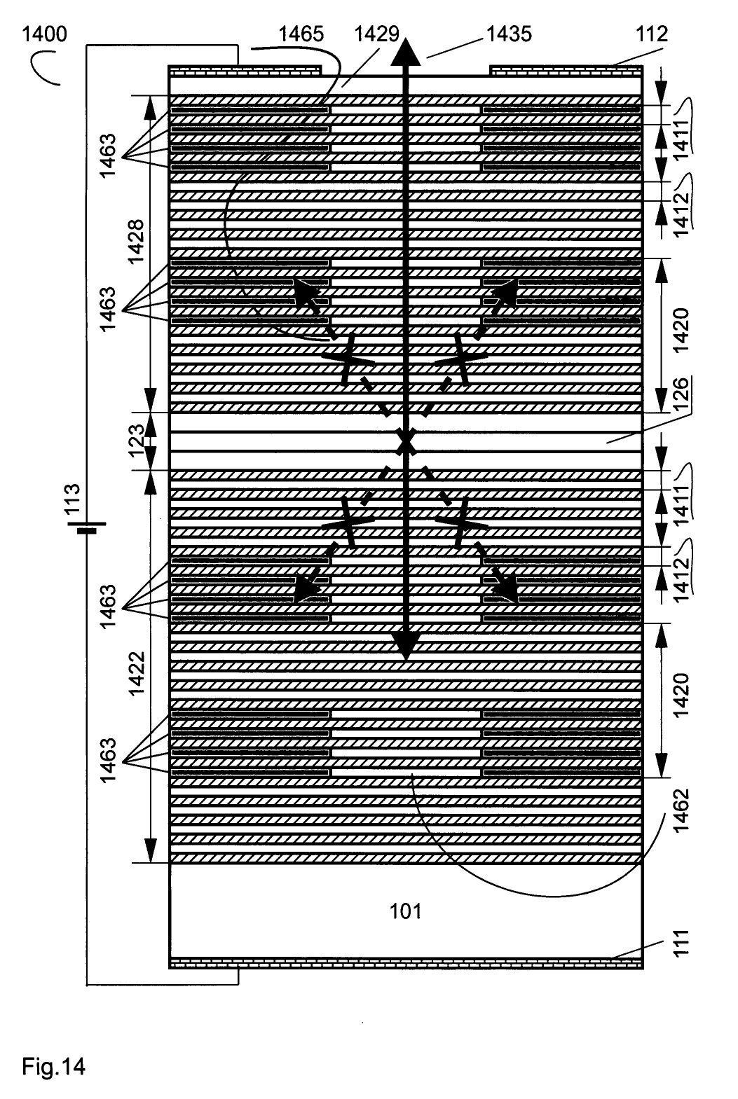

FIG. 14 shows a schematic diagram of an optoelectronic device (1400) according to yet another embodiment of the present invention. The device (1400) comprises a cavity (123) sandwiched between the bottom DBR (1422) and the top DBR (1428). The substrate (101) is contiguous to the bottom DBR (1422) from the side opposite to the cavity (123). The bottom contact (111) is mounted on the back side of the substrate (101), i.e. on the side opposite to the bottom DBR (1422). The top contact layer (1429) is contiguous to the top DBR (1428) on the side opposite to the cavity (123). The top contact (112) is mounted on the top contact layer (1429) on the side opposite to the top DBR (1428). The active region (126) is located in the cavity (123). A forward bias (113) is applied to the active region (126) via the bottom contact (111) and the top contact (112). In the embodiment of FIG. 14, the substrate (101) and the bottom DBR (1422) are preferably n-doped, and the bottom contact (111) is the n-contact. The top DBR (1428) and the top contact layer (1429) are preferably p-doped, and the top contact (112) is the p-contact.

Both the bottom DBR (1422) and the top DBR (1428) have a coarse-scale period (1420). Each coarse-scale period (1420) comprises a few layer pairs (1411) realizing a first periodicity and a few layer pairs (1412) realizing a second periodicity. In the particular embodiment (1400) shown in FIG. 14, the first periodicity is realized by four layer pairs (1411) and the second periodicity is realized by four layer pairs (1412). The device (1400) is grown epitaxially on the substrate (101), and the layers of the bottom DBR (1422) and the layers of the top DBR (1428) are grown epitaxially from the materials selected from the group consisting of GaAs, AlAs, and semiconductor alloys GaAlAs. The second periodicity realized by the layer pairs (1412) contain, one layer in each pair, formed from AlAs or GaAlAs with a high Al content, preferably higher than 90%. The epitaxially grown and processed device is further oxidized such that AlAs layers are partially oxidized and the outer part of these layers form AlO layers, and GaAlAs layers with a high Al content are partially oxidized and the outer part of these layers form GaAlO layers. The oxides form an outer part (1463) of the oxidized layers, whereas semiconductor layers (1462) in the central part of the structure are not oxidized. The oxides GaAlO and AlO are dielectrics, and the current flows through the non-oxidized parts (1462) of the layers.

The main effect of introducing oxide layers is related to their refractive indices. The refractive index contrast in a semiconductor/oxide DBR is significantly higher than that in a pure semiconductor DBR. Thus, for a wavelength close to 980 nm, the refractive index of GaAs equals 3.53, and that of AlAs equals 2.97. At the same time, the refractive index of AIO equals approximately 1.6. Thus, introducing a periodicity in the DBR having a high refractive index contrast enhances the possibility to control the angular distribution of light emission. In the device (1400) the oxide layers in the DBRs suppress the emission of light in the tilted directions (1465), and light is thus preferably emitted in the vertical direction (1435).

And one another embodiment of the present invention is possible, where layers of GaAlAs having a high Al content have different Al content. Then, the oxidation rate of the layers having a higher Al content is higher, and the oxidation depth will be larger. Such layers will have broader oxide areas. This gives an additional possibility to control the angular emission of the optoelectronic device.

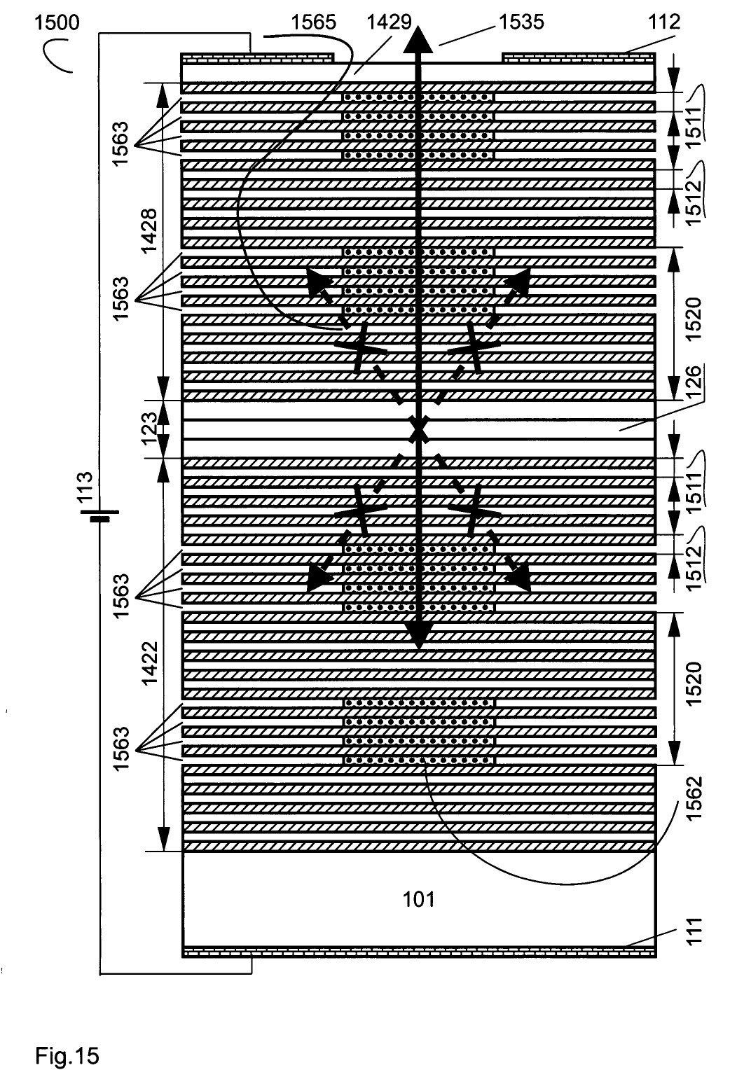

FIG. 15 shows a schematic diagram of an optoelectronic device (1500) according to a further embodiment of the present invention. Both the bottom DBR (1422) and the top DBR (1428) have a coarse-scale period (1520). Each coarse-scale period (1520) comprises a few layer pairs (1511) realizing a first periodicity and a few layer pairs (1512) realizing a second periodicity. In the particular embodiment (1500) shown in FIG. 15, the first periodicity is realized by four layer pairs (1511) and the second periodicity is realized by four layer pairs (1512). The device (1500) is grown epitaxially on the substrate (101), and the layers of the bottom DBR (1422) and the layers of the top DBR (1428) are grown epitaxially from the materials selected from the group consisting of GaAs, AlAs, and semiconductor alloys GaAlAs. The second periodicity realized by the layer pairs (1512) contain, one layer in each pair, formed from AlAs or GaAlAs with a high Al content, preferably higher than 90%. The epitaxially grown and processed device is further oxidized such that AlAs layers are partially oxidized and the outer part of these layers form AIO layers, and GaAlAs layers with a high Al content are partially oxidized and the outer part of these layers form GaAlO layers. The oxides form an outer part of the oxidized layers, whereas semiconductor layers (1562) in the central part of the structure are not oxidized. The oxidized outer parts of the layers are further etched off, forming air gaps (1563). As the refractive index of air is close to 1, the introducing of air gaps enhances the refractive index contrast in the DBRs even further as compared to semiconductor/oxide DBR of FIG. 14. Thus, introducing of air gaps (1563) enhances further the possibility to control the angular distribution of light emission. In the device (1500) the air gaps (1563) in the DBRs suppress the emission of light in the tilted directions (1565), and light is thus preferably emitted in the vertical direction (1535).

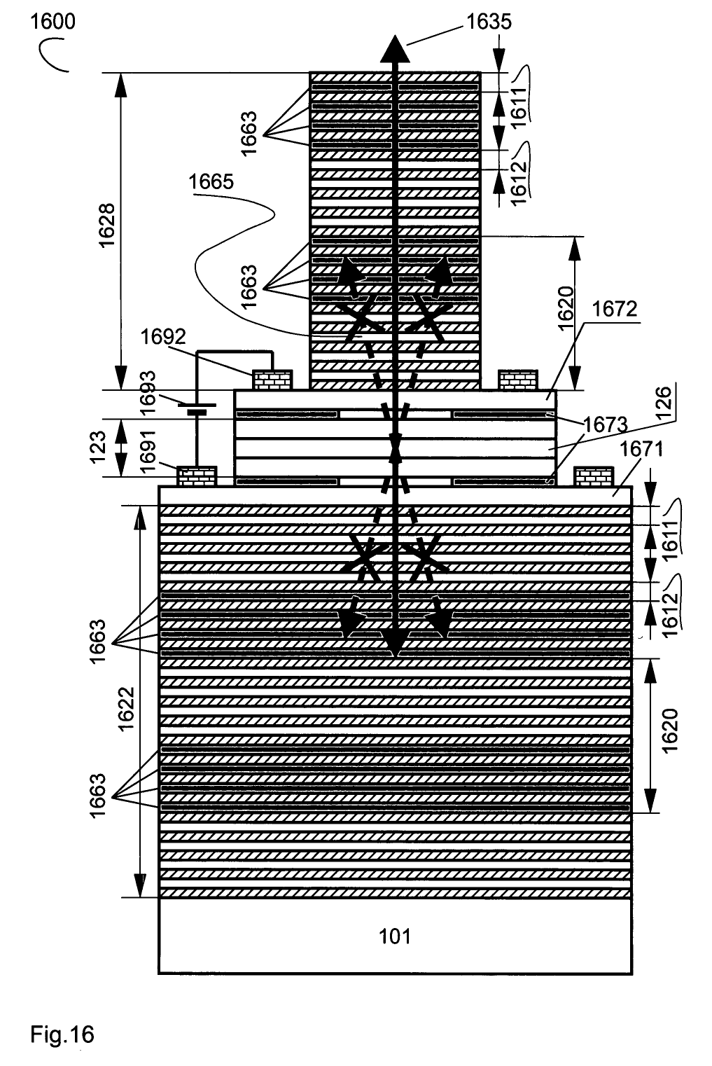

FIG. 16 shows a schematic diagram of an optoelectronic device (1600) according to one another embodiment of the present invention. In this embodiment the oxidized layers of the DBRs are oxidized completely, the DBRs are electrically insulating, and bias is applied to the active region via intracavity contacts. The device (1600) comprises a cavity (123), into which an active region (126) is placed. The cavity (123) os located between the bottom DBR (1622) and the top DBR (1628). The n-doped first current spreading layer (1671) is located between the cavity (123) and the bottom DBR (1622). The p-doped second current spreading layer (1672) is located between the cavity (123) and the top DBR (1628). The current apertures (1673) are located between the cavity (123) and the first current spreading layer (1671) and between the cavity (123) and the second current spreading layer (1672). The first contact (1691), which is an n-contact is mounted on an n-doped first current spreading layer (1671). The second contact (1692), which is a p-contact, is mounted on a p-doped second current spreading layer (1672). A forward bias (1693) is applied to the active region (126) via the first contact (1691) and the second contact (1692). The cavity (123) is preferably undoped or weakly doped. The injection current flows through the n-doped first current spreading layer (1671), the cavity (123) including the active layer (126) and the p-doped second current spreading layer (1672). The bottom DBR (1622) and the top DBR (1628) are preferably undoped to reduce the absorption loss of light due to free carrier absorption. The injection current flowing through the active region generates an optical gain in the active region. Thus light is generated in the active region. The bottom DBR (1622) and the top DBR (1628) are selected such to control the angular emission of light.

Both the bottom DBR (1622) and the top DBR (1628) have a coarse-scale period (1620). Each coarse-scale period (1620) comprises a few layer pairs (1611) realizing a first periodicity and a few layer pairs (1612) realizing a second periodicity. In the particular embodiment (1600) shown in FIG. 16, the first periodicity is realized by four layer pairs (1611) and the second periodicity is realized by four layer pairs (1612). The device (1600) is grown epitaxially on the substrate (101), and the layers of the bottom DBR (1622) and the layers of the top DBR (1628) are grown epitaxially from the materials selected from the group consisting of GaAs, AlAs, and semiconductor alloys GaAlAs. The second periodicity realized by the layer pairs (1612) contain, one layer in each pair, formed from AlAs or GaAlAs with a high Al content, preferably higher than 90%. The epitaxially grown and processed device is further oxidized such that AlAs layers are completely oxidized forming AlO layers, and GaAlAs layers with a high Al content are completely oxidized forming GaAlO layers. Oxide layers (1663) have a high refractive index contrast with neighboring semiconductor layers, which enhances the possibility to control the angular distribution of light emission. In the device (1600) the oxide layers in the DBRs suppress the emission of light in the tilted directions (1665), and light is thus preferably emitted in the vertical direction (1635).

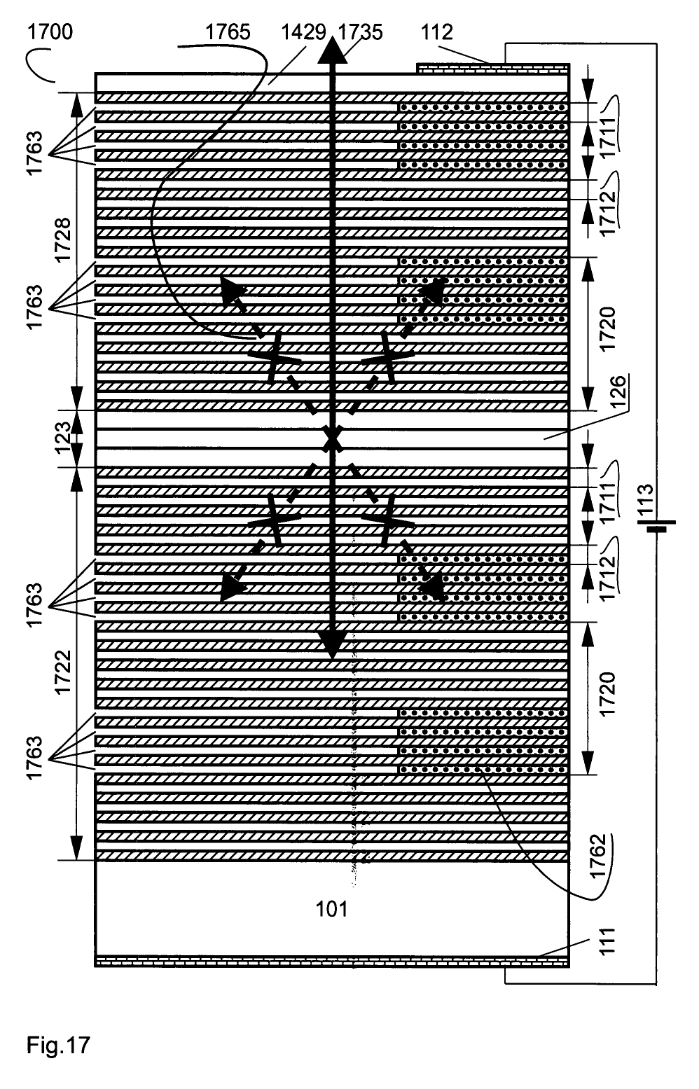

FIG. 17 shows a schematic diagram of an optoelectronic device (1700) according to yet another embodiment of the present invention. A cavity (123) in which an active region (126) is placed is sandwiched between a bottom DBR (1722) and a top DBR (1728). Both the bottom DBR (1722) and the top DBR (1728) have a coarse-scale period (1720). Each coarse-scale period (1720) comprises a few layer pairs (1711) realizing a first periodicity and a few layer pairs (1712) realizing a second periodicity. In the particular embodiment (1700) shown in FIG. 17, the first periodicity is realized by four layer pairs (1711) and the second periodicity is realized by four layer pairs (1712). The device (1700) is grown epitaxially on the substrate (101), and the layers of the bottom DBR (1722) and the layers of the top DBR (1728) are grown epitaxially from the materials selected from the group consisting of GaAs, AlAs, and semiconductor alloys GaAlAs. The second periodicity realized by the layer pairs (1712) contain, one layer in each pair, formed from AlAs or GaAlAs with a high Al content, preferably higher than 90%. The epitaxially grown and processed device is further oxidized such that AlAs layers are partially asymmetrically oxidized from one side of the device (1700) forming AlO layers, and GaAlAs layers with a high Al content are partially asymmetrically oxidized from one side of the device (1700) forming GaAlO layers. The oxides are formed on the side, from which the device (1700) is oxidized, and in the central part of the device (1700). The oxidized parts of the layers are further etched off, forming air gaps (1763). The mechanical integrity of the device (1700) is maintained by non-oxidized and non-etched parts (1762) of the layers. The same non-oxidized and non-etched parts (1762) of the layers provide injection current flowing through the active region (126). As the refractive index of air is close to 1, the introducing of air gaps enhances the refractive index contrast in the DBRs, also for the vertical optical mode. Thus, introducing of air gaps (1763) enhances further the possibility to control the angular distribution of light emission. In the device (1700) the air gaps (1763) in the DBRs suppress the emission of light in the tilted directions (1765), and light is thus preferably emitted in the vertical direction (1735).

In one another embodiment of the present invention, an optoelectronic device with asymmetrically placed air gaps can be selected such that light is preferably emitted in a tilted direction. In this case, due to the lack of symmetry, single-lobe tilted emission can be obtained. In yet another embodiment of the present invention, an optoelectronic device is oxidized asymmetrically and is not etched off. Asymmetrically positioned oxides layers allow extraction of light in a tilted direction in a single-lobe far-field pattern.

Different embodiments of the present invention are possible referring to all possible ways of fabricating conventional VCSELs. The active medium, realized as a single-layer or a multilayer structure of quantum wells, arrays of quantum wires, arrays of quantum dots or any combination thereof, may contain thin lattice mismatched layers. In another embodiment, the entire structure of the device is grown on a metamorphic (plastically relaxed) buffer, lattice-mismatched to the substrate. The top DBR or the top MIR may be formed of either semiconductor or dielectric layers, or any combination thereof. The possible material combinations are known in the art (e.g., Vertical-Cavity Surface-Emitting Lasers: Design, Fabrication, Characterization, and Applications by C. W. Wilmsen, H. Temkin, L. A. Coldren (editors), Cambridge University Press, 1999, pp. 193-232, incorporated herein by reference). Further, an optoelectronic device can contain one intracavity contact or two intracavity contacts. If at least one layer in one of the DBRs is a dielectric layer, a corresponding contact must be an intracavity contact, as shown for the device (1600) of the embodiment of FIG. 16. If all layers are semiconductor layers, intracavity contacts may still be used as an option.

It is important to emphasize a big difference between an optoelectronic device of the present invention, having a DBR or a MIR with a double periodicity, and a tilted cavity laser invented by the inventors of the present invention in the US patent application “TILTED CAVITY SEMICONDUCTOR OPTOELECTRONIC DEVICE AND METHOD OF MAKING SAME, U.S. patent application Ser. No. 10/943,044 by N. Ledentsov and V. Shchukin, filed Sep. 16, 2004. Tilted Cavity Laser (TCL) including Tilted Cavity Surface Emitting Laser is focused on wavelength-stabilized operation realized through optical loss engineering. The optimum wavelength of a TCL is governed by the intersection of the dispersion law of a cavity and the dispersion law of a MIR. The wavelength, at which the intersection occurs, corresponds to the minimum of the optical loss. Lasing occurs at this optimum wavelength, and the operation of the TCL is wavelength-stabilized. Double periodicity may be used in a MIR in one of the embodiments of the TCL to engineer optical loss and to filter out parasitic wavelengths different from the targeted optimum wavelength.

On the contrary, an optoelectronic device, e.g. light-emitting diode or laser diode of the present invention does not include any loss engineering. The wavelength stabilization is not targeted by the present invention. An optoelectronic device of the present invention can operate without wavelength stabilization. In other embodiments of the present invention, the wavelength of light emitted by the device can be stabilized, however not due to the minimum loss criterion in the epitaxial structure, but by a conventional mechanism used in VCSELs, e.g. by a finite lateral oxide aperture (similar to the aperture (1673) in the device (1600)).

In yet another embodiment of the present invention, an optoelectronic device does not contain any cavity, and the active region is placed in one of the layers of a DBR or a MIR. The DBR or the MIR has a double periodicity prohibiting emission of light in an interval of angles tilted with respect to the intentionally selected direction of the light emission.

A lot of further modifications can be made to the described embodiments of the present invention. Photonic crystals can be used for better mode control and light extraction efficiency. Different designs of multilayer interference reflectors used as Bragg reflectors can be applied. Multiple sections and cavities with different functionalities can be introduced for wavelength tuning, intensity modulation and photocurrent control.

Optoelectronic device of the present invention can operate as a light-emitting diode, where certain directions of light emission are suppressed, resulting in a significantly better directionality of the emitted light from the device. In another embodiment of the present invention an optoelectronic device operates as a superluminescent light-emitting diode. In yet another embodiment of the present invention, an optoelectronic device operates as a laser diode. Such laser diode can be a Vertical Cavity Surface Emitting Laser (VCSEL) or a Tilted Cavity Surface Emitting Laser (TCSEL).

Further embodiment of the present invention is possible, where an optoelectronic device operates as a single photon emitter. Such single photon emitter has a significantly better directionality of the emitted photons than the conventional single photon emitter. And yet another embodiment of the present invention is possible, where an optoelectronic device operates as an emitter of entangled photons.

And one another embodiment of the present invention is possible, where the active region is pumped optically. Optical pumping generates non-equilibrium carriers in the active region. The carriers recombine generating light which is emitted with a required directionality.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

The present invention should not be understood as limited to the specific embodiments set out above but to include all possible embodiments which are embodied within a scope encompassed and equivalents thereof with respect to the features set out in the appended claims. Accordingly, it is to be understood that the embodiments of the invention herein described are merely illustrative of the application of the principles of the invention. Reference herein to details of the illustrated embodiments is not intended to limit the scope of the claims, which themselves recite those features regarded as essential to the invention.

The following patent and non-patent references are incorporated herein by reference in their entireties:

### U.S. Patents

U.S. Pat. No. 7,031,360. Apr. 18, 2006. Ledentsov, N., Shchukin, V. “Tilted cavity semiconductor laser (TCSL) and method of making same”

### U.S. Patent Applications

Ser. No. 10/943,044. Sep. 16, 2004. Ledentsov, N., Shchukin, V. “Tilted cavity semiconductor optoelectronic device and method of making same”
Ser. No. 11/099,360, Apr. 5, 2005. Ledentsov, N., Shchukin, V. “Optoelectronic device based on an antiwaveguiding cavity”
Ser. No. 11/194,181, Aug. 1, 2005. Ledentsov, N., Shchukin, V. “Tilted cavity semiconductor device and method of making same”
60/814,054, Jun. 16, 2006, Shchukin, V., Ledentsov, N. “Resonant cavity optoelectronic device with suppressed parasitic modes”

### Other Publications

A. Yariv, P. Yeh, Optical Waves in Crystals. Propagation and Control of Laser Radiation, Wiley, (1984), Chapter 6.
Vertical-Cavity Surface-Emitting Lasers: Design Fabrication, Characterization, and Applications, by C. W. Wilmsen, H. Temkin, L. A. Coldren (editors), Cambridge University Press, 1999, pp. 193-232.
N. N. Ledentsov and V. A. Shchukin “Novel concepts for injection lasers” SPIE Optical Engineering, Volume 41, Issue 12, pp. 3193-3203 (2002)
N. Ledentsov, V. A. Shchukin, S. S. Mikhrin, I. L. Krestnikov, A. V. Kozhukhov, A. R. Kovsh, L. Ya. Karachinsky, M. V. Maximov, I. I. Novikov and Yu. M. Shemyakov “Wavelength-stabilized tilted cavity quantum dot laser” Semiconductor. Science and Technology, vol. 19, pp. 1183-1188 (2004).
V. A. Shchukin, N. N. Ledentsov, S. S. Mikhrin, I. L. Krestnikov, A. V. Kozhukhov, A. R. Kovsh, L. Ya. Karachinsky, M. V. Maximov, I. I. Novikov, and Yu. M. Shemyakov, “Tilted Cavity Laser”. In: Nanomodeling, ed. by A. Lakhtakia and S. A. Maksimenko, Proc. SPE 5509, pp. 61-71 (2004), SPIE, Belingham, Wash.
N. N. Ledentsov, V. A. Shchukin, A. R. Kovsh, S. S. Mikhrin, I. L. Krestnikov, A. V. Kozhukhov, N. Yu. Gordeev, L. Ya. Karachinsky, M. V. Maximov, I. I. Novikov, Yu. M. Shemyakov, “Edge and Surface-Emitting Tilted Cavity Lasers”, Proceedings. SPIE 5722, pp. 130-146 (2005).
V. A. Shchukin, N. N. Ledentsov, N. Yu. Gordeevb, L. Ya. Karachinsky, N. V. Kryzhanovskaya, S. M. Kuznetsovb, M. B. Lifshits, M. V. Maximov, I. I. Novikov, Yu. M. Shemyakov, T. Kettler, K. Posilovic, and D. Bimberg, “High brilliance photonic band crystal lasers”, Proc. SPIE 6350, pp. 635005-1-635005-15 (2006).
M. B. Lifshits, V. A. Shchukin, N. N. Ledentsov, and D. Bimberg, “Resonance wavelength in planar multilayer waveguides: control and complete suppression of temperature sensitivity”, Semiconductor Science and Technology, vol. 22, pp. 380-384 (2007).

What is claimed is:

1. A semiconductor optoelectronic device comprising:
a) at least one multilayer interference reflector;
b) at least two periodicities forming said at least one multilayer interference reflector, wherein
at least one periodicity of at least two periodicities is selected such that it forbids emission of light in an interval of angles tilted with respect to an intentionally selected direction for light emission;
c) at least one generating element further comprising a region which generates light when non-equilibrium carriers are injected into the light generating element;
d) means of the injection of non-equilibrium carriers into the light generating element.

2. The semiconductor optoelectronic device of claim 1, further comprising a cavity.

3. The semiconductor optoelectronic device of claim 2, wherein the light generating element is placed in the cavity.

4. The semiconductor optoelectronic device of claim 1, wherein the semiconductor optoelectronic device is selected from the group consisting of:
a) a light-emitting diode;
b) a superluminescent light-emitting diode;
c) a diode laser;
d) a single photon emitter;
e) an emitter of entangled photons.

5. The semiconductor optoelectronic device of claim 4, wherein the semiconductor optoelectronic device is a diode laser; wherein the diode laser is selected from a group consisting of:
a) a vertical cavity laser;
b) a tilted cavity surface emitting laser;
c) an edge-emitting laser;
d) a tilted cavity edge-emitting laser operating in a high-order vertical optical mode;
e) an edge-emitting mode locked laser;
f) an edge-emitting distributed feedback laser.

6. The semiconductor optoelectronic device of claim 1, wherein the multilayer interference reflector is formed by the layers selected from the group consisting of:
a) layers formed of semiconductor materials;
b) layers formed of dielectrics; and
c) air gaps.

7. The semiconductor optoelectronic device of claim 6, wherein layers formed by dielectrics are formed of the materials selected from the group consisting of:
a) AlO; and
b) alloy GaAlO.

8. The semiconductor optoelectronic device of claim 7, wherein
a) layers of AlO are formed by the method selected from the group of methods consisting of:
i) partial oxidation of the layers of AlAs; and
ii) complete oxidation of the layers of AlAs; and
b) layers of GaAlO are formed by the method selected from the group of methods consisting of:
iii) partial oxidation of the layers of GaAlAs; and
iv) complete oxidation of the layers of GaAlAs.

9. The semiconductor optoelectronic device of claim 1, wherein said at least two periodicities forming said at least one multilayer interference reflector further comprise
a) a first periodicity; further comprising
i) at least one layer having a low refractive index of the first periodicity; and
ii) at least one layer having a high refractive index of the first periodicity; and
b) a second periodicity, further comprising
iii) at least one layer having a low refractive index of the second periodicity; and
iv) at least one layer having a high refractive index of the second periodicity.

10. The semiconductor optoelectronic device of claim 9, wherein the second periodicity is distinct from the first periodicity by at least one feature selected from the group of features consisting of:
a) the low refractive index of the second periodicity differs from the low refractive index of the first periodicity;
b) the high refractive index of the second periodicity differs from the high refractive index of the first periodicity;
c) the thickness of the layer of the second periodicity having the low refractive index of the second periodicity differs from the thickness of the layer of the first periodicity having the low refractive index of the first periodicity;
d) the thickness of the layer of the second periodicity having the high refractive index of the second periodicity differs from the thickness of the layer of the first periodicity having the high refractive index of the first periodicity; and
e) any combination of a) through d).

11. The semiconductor optoelectronic device of claim 6, wherein at least one layer formed of semiconductor materials is formed of a material selected from the group consisting of:
i) III-V semiconductor materials; and
ii) alloys based on III-V semiconductor materials;
wherein the III-V semiconductor materials are selected from the group of binary compounds of an element A, selected from the group consisting of Al, Ga, and In; and an element B, selected from the group consisting of N, P, As, and Sb.
